(19) United States
(12) Patent Application Publication
(10) Pub. No.: US 2025/0355364 A1
(43) Pub. Date: Nov. 20, 2025

(54) MODELLING OF MULTI-LEVEL ETCH PROCESSES

(71) Applicant: ASML NETHERLANDS B.V., Veldhoven (NL)

(72) Inventors: Yongfa FAN, Cupertino, CA (US); Mu FENG, San Jose, CA (US)

(73) Assignee: ASML NETHERLANDS B.V., Veldhoven (NL)

(21) Appl. No.: 18/871,784

(22) PCT Filed: Jul. 26, 2023
(86) PCT No.: PCT/EP2023/070661

§ 371 Date: Dec. 4, 2024

Related U.S. Application Data
(60) Provisional application No. 63/400,973, filed on Aug. 25, 2022.

(51) Int. Cl. G03F 7/00

(52) U.S. Cl. CPC G03F 7/705; G03F 7/70625; G03F 7/706837; G03F 7/706841

(57) ABSTRACT

Methods, systems, and computer software for predicting after-etch profiles of features at varying depths. A method can include accessing after-development resist profiles of features. The method can also include applying an etch bias model on the after-development resist profiles to obtain the after-etch profiles, where the etch bias model correlates an etch bias with an etch depth.

### CROSS-REFERENCE WITH RELATED APPLICATIONS

This application claims priority of U.S. application 63/400,973 which was filed on Aug. 25, 2022 and which is incorporated herein in its entirety by reference

### TECHNICAL FIELD

The description herein relates generally to multi-level etch processes. More particularly, the disclosure includes apparatus, methods, and computer programs for performing and modelling multi-level etch processes.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g., comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

Systems, methods, and computer software are disclosed predicting after-etch profiles of features at varying depths. In one aspect, a method includes accessing after-development resist profiles of features; and applying an etch bias model on the after-development resist profiles to obtain the after-etch profiles, where the etch bias model correlates an etch bias with an etch depth.

In some variations, the etch bias can be correlated with the etch depth based on a lateral location of a feature. The after-development resist profiles can be predicted resist contours and the etch bias model can include a term indicating a convolution of a mask and a filter, the convolution calculating the etch depth. The after-etch profiles can be after-etch CDs. The determining of the after-development resist profiles can include applying a resist model to a patterning device.

In some variations, the determining the etch depth can be based on distances of the features from a reference location of a staircase feature mask. The staircase feature mask can indicate locations of the features, the determining of the etch depth comprising convolving a staircase formation mask and a filter, the convolution generating a depth map representing the depths at locations of the features.

In some variations, the method can further comprise calibrating the etch bias model by determining a coefficient that modifies an etch bias contribution of the convolution, the coefficient calculated based on gauge data having etch bias values for the features at their respective depths. The gauge data can be CD and/or EP gauge data for the features. The coefficient can be calculated using a linear solver to fit measurements of printed features on printed wafers.

In some variations, the method can include calculating the etch bias with the etch bias model, the etch bias representing displacements of the features from target feature locations, the after-etch profiles generated utilizing the etch bias. The filter can be a square filter or a multi-gaussian filter.

In some variations, the etch bias model can be a machine learning model trained with gauge data, the method further including calculating the etch bias with the machine learning model, the etch bias representing displacements of the features from target feature locations, the predicted after-etch profiles generated utilizing the etch bias. The machine learning model can be a convolutional neural network and the filter can be a convolutional neural network filter comprising weights used to represent the etch depth at the locations of the features. The machine learning model can be trained with measurements of training features from printed wafers.

In an interrelated aspect, there can be a non-transitory computer readable medium having instructions recorded thereon for predicting after-etch profiles of features at varying depths, the instructions when executed by a computer having at least one programmable processor cause operations comprising any of the operations in the above method embodiments.

In an interrelated aspect, there can be a system for predicting after-etch profiles of features at varying depths, the system comprising: at least one programmable processor; and a non-transitory computer readable medium having instructions recorded thereon, the instructions when executed by a computer having the at least one programmable processor cause operations comprising any of the operations in the above method embodiments.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment of the present disclosure.

FIG. 2 illustrates an exemplary flow chart for simulating lithography in a lithographic projection apparatus, according to an embodiment of the present disclosure.

FIG. 3 illustrates an exemplary portion of a structure etched in a staircase formation, according to an embodiment of the present disclosure.

FIG. 4 illustrates exemplary features that narrow with depth in a staircase formation, according to an embodiment of the present disclosure.

FIG. 5 illustrates an exemplary depth dependence of features based on their lateral locations in a design layout, according to an embodiment of the present disclosure.

FIG. 6 illustrates an exemplary depth map based on locations of features in a patterning device, according to an embodiment of the present disclosure.

FIG. 7 illustrates an exemplary process flow for generating simulated features that incorporate an etch bias, according to an embodiment of the present disclosure.

FIG. 8 illustrates an exemplary process flow for generating simulated features utilizing a machine learning model, according to an embodiment of the present disclosure.

FIG. 9 illustrates an exemplary filter for use with a machine learning model, according to an embodiment of the present disclosure.

FIG. 10 is a block diagram of an example computer system, according to an embodiment of the present disclosure.

FIG. 11 is a schematic diagram of a lithographic projection apparatus, according to an embodiment of the present disclosure.

FIG. 12 is a schematic diagram of another lithographic projection apparatus, according to an embodiment of the present disclosure.

FIG. 13 is a detailed view of the lithographic projection apparatus, according to an embodiment of the present disclosure.

FIG. 14 is a detailed view of the source collector module of the lithographic projection apparatus, according to an embodiment of the present disclosure.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

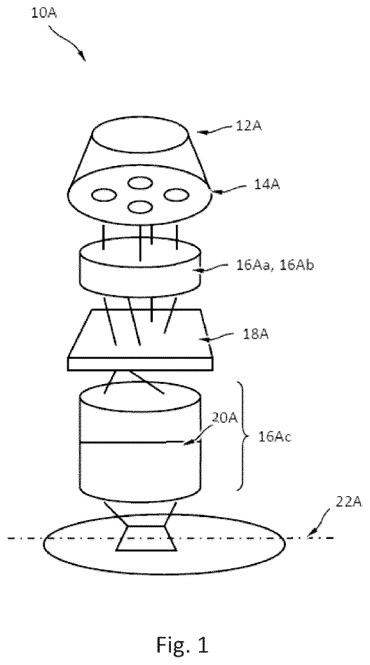

FIG. 1 illustrates a block diagram of various subsystems of a lithographic projection apparatus 10A, according to an embodiment of the present disclosure. Major components are a radiation source 12A, which may be a deep-ultraviolet excimer laser source or other type of source including an extreme ultraviolet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device 18A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac. An aerial image (AI) is the radiation intensity distribution at substrate level. A resist model can be used to calculate the resist image from the aerial image, an example of which can be found in U.S. Patent Application Publication No. US 2009-0157630, the disclosure of which is hereby incorporated by reference in its entirety. The resist model is related only to properties of the resist layer (e.g., effects of chemical processes which occur during exposure, post-exposure bake (PEB) and development). Optical properties of the lithographic projection apparatus (e.g., properties of the illumination, the patterning device and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each which is hereby incorporated by reference in its entirety.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

The mask transmission function may have a variety of different forms. One form is binary. A binary mask transmission function has either of two values (e.g., zero and a positive constant) at any given location on the patterning device. A mask transmission function in the binary form may be referred to as a binary mask. Another form is continuous. Namely, the modulus of the transmittance (or reflectance) of the patterning device is a continuous function of the location on the patterning device. The phase of the transmittance (or reflectance) may also be a continuous function of the location on the patterning device. A mask transmission function in the continuous form may be referred to as a continuous tone mask or a continuous transmission mask (CTM). For example, the CTM may be represented as a pixelated image, where each pixel may be assigned a value between 0 and 1 (e.g., 0.1, 0.2, 0.3, etc.) instead of binary value of either 0 or 1. In an embodiment, CTM may be a pixelated gray scale image, where each pixel having values (e.g., within a range [−255, 255], normalized values within a range [0, 1] or [−1, 1] or other appropriate ranges).

The thin-mask approximation, also called the Kirchhoff boundary condition, is widely used to simplify the determination of the interaction of the radiation and the patterning device. The thin-mask approximation assumes that the thickness of the structures on the patterning device is very small compared with the wavelength and that the widths of the structures on the mask are very large compared with the wavelength. Therefore, the thin-mask approximation assumes the electromagnetic field after the patterning device is the multiplication of the incident electromagnetic field with the mask transmission function. However, as lithographic processes use radiation of shorter and shorter wavelengths, and the structures on the patterning device become smaller and smaller, the assumption of the thin-mask approximation can break down. For example, interaction of the radiation with the structures (e.g., edges between the top surface and a sidewall) because of their finite thicknesses (“mask 3D effect” or “M3D”) may become significant. Encompassing this scattering in the mask transmission function may enable the mask transmission function to better capture the interaction of the radiation with the patterning device. A mask transmission function under the thin-mask approximation may be referred to as a thin-mask transmission function. A mask transmission function encompassing M3D may be referred to as a M3D mask transmission function.

According to an embodiment of the present disclosure, one or more images may be generated. The images includes various types of signal that may be characterized by pixel values or intensity values of each pixel. Depending on the relative values of the pixel within the image, the signal may be referred as, for example, a weak signal or a strong signal, as may be understood by a person of ordinary skill in the art. The term “strong” and “weak” are relative terms based on intensity values of pixels within an image and specific values of intensity may not limit scope of the present disclosure. In an embodiment, the strong and weak signal may be identified based on a selected threshold value. In an embodiment, the threshold value may be fixed (e.g., a midpoint of a highest intensity and a lowest intensity of pixel within the image. In an embodiment, a strong signal may refer to a signal with values greater than or equal to an average signal value across the image and a weak signal may refer to signal with values less than the average signal value. In an embodiment, the relative intensity value may be based on percentage. For example, the weak signal may be signal having intensity less than 50% of the highest intensity of the pixel (e.g., pixels corresponding to target pattern may be considered pixels with highest intensity) within the image. Furthermore, each pixel within an image may considered as a variable. According to the present embodiment, derivatives or partial derivative may be determined with respect to each pixel within the image and the values of each pixel may be determined or modified according to a cost function based evaluation and/or gradient based computation of the cost function. For example, a CTM image may include pixels, where each pixel is a variable that can take any real value.

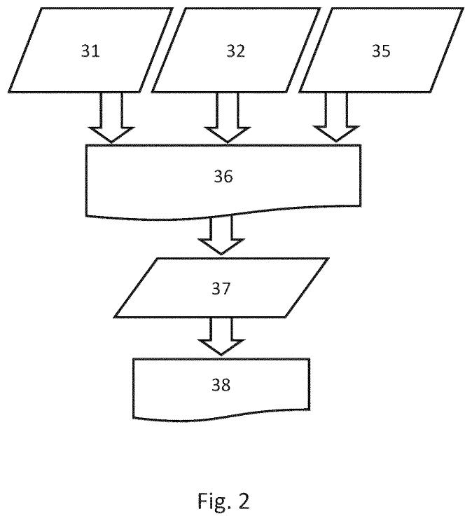

FIG. 2 illustrates an exemplary flow chart for simulating lithography in a lithographic projection apparatus, according to an embodiment of the present disclosure. Source model 31 represents optical characteristics (including radiation intensity distribution and/or phase distribution) of the source. Projection optics model 32 represents optical characteristics (including changes to the radiation intensity distribution and/or the phase distribution caused by the projection optics) of the projection optics. Design layout model 35 represents optical characteristics of a design layout (including changes to the radiation intensity distribution and/or the phase distribution caused by design layout 33), which is the representation of an arrangement of features on or formed by a patterning device. Aerial image 36 can be simulated from design layout model 35, projection optics model 32, and design layout model 35. Resist image 38 can be simulated from aerial image 36 using resist model 37. Simulation of lithography can, for example, predict contours and CDs in the resist image.

More specifically, it is noted that source model 31 can represent the optical characteristics of the source that include, but not limited to, numerical aperture settings, illumination sigma (o) settings as well as any particular illumination shape (e.g., off-axis radiation sources such as annular, quadrupole, dipole, etc.). Projection optics model 32 can represent the optical characteristics of the projection optics, including aberration, distortion, one or more refractive indexes, one or more physical sizes, one or more physical dimensions, etc. Design layout model 35 can represent one or more physical properties of a physical patterning device, as described, for example, in U.S. Pat. No. 7,587,704, which is incorporated by reference in its entirety. The objective of the simulation is to accurately predict, for example, edge placement, aerial image intensity slope and/or CD, which can then be compared against an intended design. The intended design is generally defined as a pre-OPC design layout which can be provided in a standardized digital file format such as GDSII or OASIS or other file format.

From this design layout, one or more portions may be identified, which are referred to as “clips”. In an embodiment, a set of clips is extracted, which represents the complicated patterns in the design layout (typically about 50 to 1000 clips, although any number of clips may be used). These patterns or clips represent small portions (i.e. circuits, cells or patterns) of the design and more specifically, the clips typically represent small portions for which particular attention and/or verification is needed. In other words, clips may be the portions of the design layout, or may be similar or have a similar behavior of portions of the design layout, where one or more critical features are identified either by experience (including clips provided by a customer), by trial and error, or by running a full-chip simulation. Clips may contain one or more test patterns or gauge patterns.

An initial larger set of clips may be provided a priori by a customer based on one or more known critical feature areas in a design layout which require particular image optimization. Alternatively, in another embodiment, an initial larger set of clips may be extracted from the entire design layout by using some kind of automated (such as machine vision) or manual algorithm that identifies the one or more critical feature areas.

In a lithographic projection apparatus, as an example, a cost function may be expressed as

$$CF ( {z}_{1} , {z}_{2} , ⋯ , {z}_{N} ) = {\sum }_{p = 1}^{P} {w}_{p} {f}_{p}^{2} ( {z}_{1} , {z}_{2} , ⋯ , {z}_{N} ) \qquad ( Eq . 1 )$$

where (z₁, z₂, . . . , z_{N}) are N design variables or values thereof. fₚ(z₁, z₂, . . . , z_{N}) can be a function of the design variables (z₁, z₂, . . . , z_{N}) such as a difference between an actual value and an intended value of a characteristic for a set of values of the design variables of (z₁, z₂, . . . , z_{N}). wₚ is a weight constant associated with fₚ(z₁, z₂, . . . , z_{N}). For example, the characteristic may be a position of an edge of a pattern, measured at a given point on the edge. Different fₚ(z₁, z₂, . . . , z_{N}) may have different weight wₚ. For example, if a particular edge has a narrow range of permitted positions, the weight wₚ for the fₚ(z₁, z₂, . . . , z_{N}) representing the difference between the actual position and the intended position of the edge may be given a higher value. fₚ(z₁, z₂, . . . , z_{N}) can also be a function of an interlayer characteristic, which is in turn a function of the design variables (z₁, z₂, . . . , z_{N}). Of course, CF(z₁, z₂, . . . , z_{N}) is not limited to the form in Eq. 1. CF(21, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, an interlayer characteristic, or a combination thereof. In one embodiment, the design variables (z₁, z₂, . . . , z_{N}) comprise one or more selected from dose, global bias of the patterning device, and/or shape of illumination. Since it is the resist image that often dictates the pattern on a substrate, the cost function may include a function that represents one or more characteristics of the resist image. For example, fₚ(z₁, z₂, . . . , z_{N}) can be simply a distance between a point in the resist image to an intended position of that point (i.e., edge placement error EPEₚ(z₁, z₂, . . . , z_{N}). The design variables can include any adjustable parameter such as an adjustable parameter of the source, the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput.

As used herein, the term “patterning process” means a process that creates an etched substrate by the application of specified patterns of light as part of a lithography process.

As used herein, the term “patterning device” can refer to an actual physical mask that affects/blocks incoming light during a lithography process but can also refer to a mathematical/simulated construction of such a mask. For example, a patterning device can be a simulated resist mask, with the features of the resist mask adjusted/optimized by various processes as described herein.

As used herein, the term “target pattern” means an idealized pattern that is to be etched on a substrate.

As used herein, the term “printed pattern” means the physical pattern on a substrate that was formed based on a design layout. The printed pattern can include, for example, vias, contact holes, troughs, channels, depressions, edges, or other two and three dimensional features resulting from a lithography process.

As used herein, the term “process model” means a model that includes one or more models that simulate a patterning process. For example, a process model can include any combination of: an optical model (e.g., that models a lens system/projection system used to deliver light in a lithography process and may include modelling the final optical image of light that goes onto a photoresist), a mask model, a resist model (e.g., that models physical effects of the resist, such as chemical effects due to the light), an OPC model (e.g., that can be used to make design layouts and may include sub-resolution resist features (SRAFs), etc.), an imaging device model (e.g., that models what an imaging device may image from a printed pattern).

As used herein, the term “imaging device” means any number or combination of devices and associated computer hardware and software that can be configured to generate images of a target, such as the printed pattern or portions thereof. Non-limiting examples of an imaging devices can include: scanning electron microscopes (SEMs), x-ray machines, etc.

As used herein, the term “calibrating” means to modify (e.g., improve or tune) and/or validate, such as the process model.

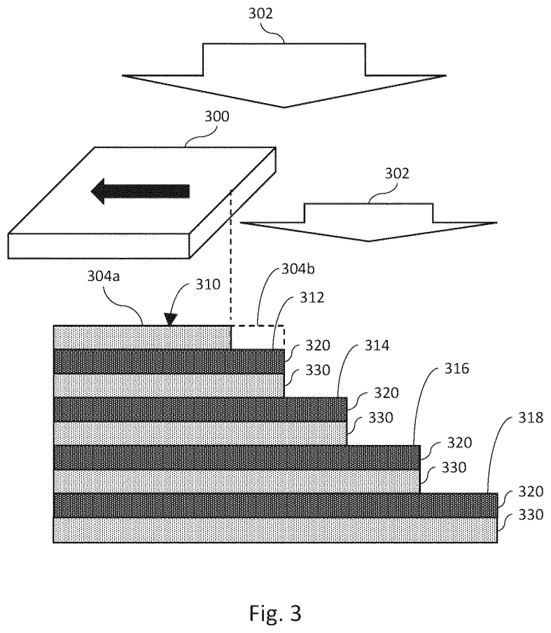

FIG. 3 illustrates an exemplary portion of a structure etched in a staircase formation, according to an embodiment of the present disclosure. In some lithographic manufacturing processes, features such as lines, vias, etc. can be formed of conductive material to form a printed pattern such as for an integrated circuit or computer memory. Such features can be printed at one or more levels, with one level above the other and with some features connected between levels to form a three-dimensional printed pattern. One specific example of such a three-dimensional printed pattern can be found in NAND memory. While the present disclosure is discussed utilizing a structure similar to that found in NAND memory, the concepts described herein can be utilized in any other application that may include printing complex three-dimensional structures.

A simplified depiction of a structure 310 having a staircase formation is shown in FIG. 3. Such a structure can be formed having layers that have been removed in stages utilizing staircase formation mask 300 with an etching process 302 (e.g., a plasma etch or chemical etch). The structure 310 depicted in FIG. 3 has four layers 312, 314, 316, 318, with each layer having, for example, a conductive layer 320 (e.g., a tungsten layer) and an oxide layer 330 (e.g., a silicon-oxide layer). The last step in producing structure 310 is shown by the staircase formation mask being moved to a position to block a portion 304a (e.g., of an oxide layer) resulting in material 304b being removed.

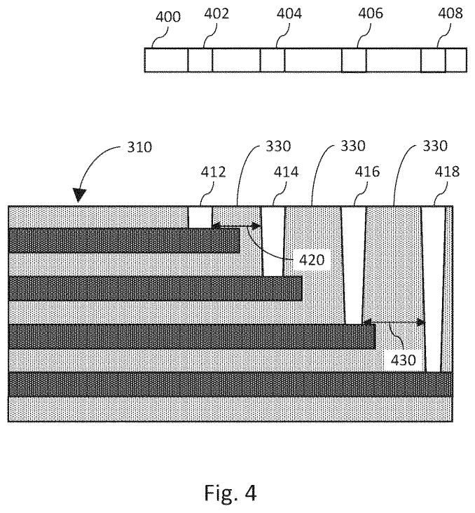

FIG. 4 illustrates exemplary features that narrow with depth in a staircase formation, according to an embodiment of the present disclosure. Continuing from the example of FIG. 3, once the staircase formation is formed, the structure 310 can be filled with additional oxide 330 to replace that which was removed during the staircase formation process. Then, a patterning device (e.g., staircase feature mask 400) having patterns 402, 404, 406, 408, can be utilized to form features 412, 414, 416, 418 (e.g., contact holes or vias as typically depicted herein) by etching into the oxide down to a particular conductive layer.

Due to the small sizes involved, it can be important for some dimensions to be close to the dimension specifications that may be set forth for a target pattern. One example of such a dimension can include distances between adjacent features. One dimension between feature 412 and feature 414 is depicted in FIG. 4 by dimension 420. It can be seen that at comparatively shallow locations, the dimension at the depth shown may be quite close to the corresponding dimension at the surface of structure 310, which in turn may be close to the specifications of the target pattern. In contrast, due to some etching processes removing less material when etching a deeper feature (e.g., features 416, 418), the dimension 430 between such features can significantly deviate from that set forth by the target pattern. However, in some embodiments, more material may be removed at deeper locations thus acting to widen features with increasing depth. Any such deviations can be accounted for by optimizing the manufacturing process, including, for example, determining optimized patterning devices (e.g., resist masks), when such deviations can be accurately predicted. Also, while the present disclosure illustrates only a few layers, in a more realistic application, such a structure can have tens or even hundreds of layers and as such, the process of determining the effect of etching at various depths can be computationally expensive.

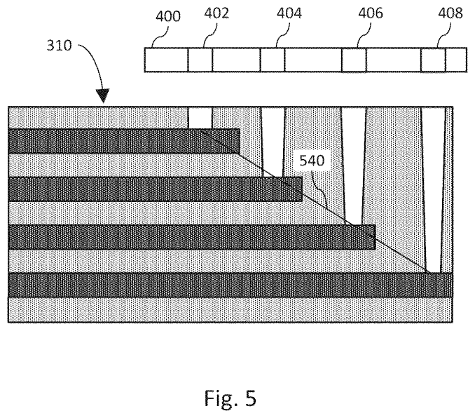

FIG. 5 illustrates an exemplary depth dependence of features based on their lateral locations in a design layout, according to an embodiment of the present disclosure. Structure 310 is reproduced from FIG. 4, with FIG. 5 also showing staircase feature mask 410 with features 402, 404, 406, 408. Predicting after-etch profiles of features at varying depths can include accessing after-development resist profiles of features (e.g., predicted or measured wafer resist contours). Resist contours can determined by simulating the lithography process given a particular patterning device, e.g., performing resist modelling as described herein. Resist contours may also result from measurement using an optical or charged particle metrology or inspection apparatus. Embodiments of the present disclosure include applying an etch model (e.g., an etch bias model) on the after-development resist profiles to obtain after-etch profiles, where the etch bias model correlates etch bias with etch depth. For example, the after-etch profiles can be after-etch CDs. Accordingly, determining the after-development resist profiles can include applying a resist model to a patterning device. It can be seen by the line representing depth 540 drawn that the depth dependence (or correlation) may be linear, though other mathematical forms of dependencies are also contemplated as described further herein. This depth correlation can then be built into models used to determine or optimize etching processes, resist masks, etc. The model can be an etch model, etch bias model, a machine learning model, or a non-machine learning model.

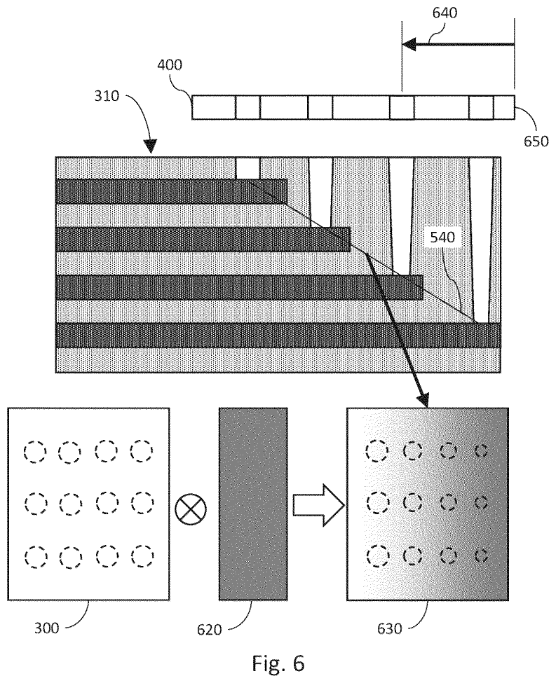

FIG. 6 illustrates an exemplary depth map based on locations of features in a patterning device, according to an embodiment of the present disclosure. In some embodiments, the patterning device can include a staircase feature mask 400 indicating the locations of the features at the different levels of the staircase formation (as shown in structure 310). In the example of FIG. 6, determining of the etch depth can include convolving a mask (e.g., staircase formation mask 300) and a filter 620, with the convolution generating a depth map 630 representing the depths at locations of the features. Depth map 630 is depicted by the shading increasing from left to right, as generally produced by the convolution with a constant value filter of the sort illustrated by filter 620. For illustrative purposes, the locations of features 402-408 are shown where they would be relative to the staircase formation mask 300 and also shown how the size of the features decreases at corresponding locations on depth map 630. The etch bias can be correlated with etch depth based on a lateral location (e.g., distances such as distance 640) of the features from a reference location 650 (e.g., an edge) of the patterning device (e.g., staircase feature mask 400). For the example linear relationship of depth 540 with distance 640 depicted in FIG. 6, the filter can be a square filter, which results in a linear convolution that can represent a linear depth dependence. As used herein, “square” means a square function, e.g., a two-term Heaviside step function where the filter is: 0 outside a boundary and 1 inside. The term “square” thus does not mean that the square filter is necessarily geometrically square or has any particular geometric shape. In other embodiments, the filter can be a multi-gaussian filter that can act to smooth transitions where a depth profile begins. For example, the depth profile can smoothly transition from a constant depth (e.g., at the left portion of the structure 310) to a linearly decreasing function as shown. Other filters can include ones having a linear transition themselves, resulting a different depth dependence after the convolution. In general, the filter can have any value distribution such that, when convolved with the staircase mask, that the depth dependence of the features in the staircase mask are accurately produced by the convolution.

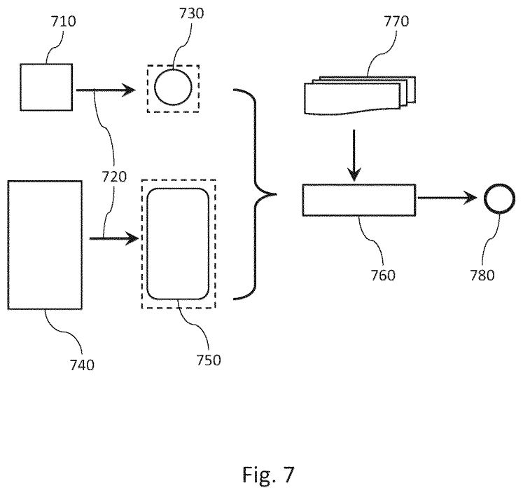

The present disclosure is not limited to any specific process or type of model configured to predict etch profiles from resist profiles. FIG. 7 illustrates an exemplary process flow for generating simulated features that incorporate an etch bias, according to an embodiment of the present disclosure. The etch bias can be a shift in features relative to a target pattern. Such biasing can occur due to shifts in dimensions as described herein but may also be intentional and due to shifts caused by optimizing the lithography process to reduce some shifts in critical locations. Accordingly, the disclosed modelling processes can include determining an etch bias, which may be an output of the model or may be a parameter to be optimized (e.g., reduced) during optimization of a lithographic process. One exemplary etch bias model is shown below in Eq. 2:

$$EB = {C}_{bias} + {\sum }_{i} {c}_{i} \cdot {X}_{i} + {\sum }_{j} {c}_{j} \cdot ( {filter}_{j} ⊗ mask ) \qquad ( Eq . 2 )$$

Here, C_{bias} is a constant bias that can be applied to represent a systematic bias present in the predicted contours. The summation term is over the etch bias terms (Xᵢ) and represents the contribution of different physical processes in determining the overall etch bias, e.g., loading, aspect ratio, etc. The coefficients cᵢ can be weights applied based on empirical measurements or simulation.

The last term in Eq. 2 describes a convolution of a mask (e.g., staircase formation mask 300) and one or more filters (e.g., filter 620), the convolution calculating the etch depth (e.g., by generating depth map 630). While the example of using a single filter is illustrated in FIGS. 6 and 7, it is contemplated that any number (j) filters can be convolved with the mask. Accordingly, the summation adds the contributions of all j convolutions with j filters. In some embodiments, calibrating the etch bias model discussed above can include determining coefficient(s) (Cⱼ) that modify the etch bias contribution of the convolution. The coefficient (Cⱼ) can be calculated based on gauge data having etch bias values for the features at their respective depths. In some embodiments, the gauge data can be CD and/or EP gauge data for the features. In some embodiments, the coefficient (Cⱼ) can be determined utilizing a linear solver based on measurements of printed features on printed wafers.

Utilizing the above, the disclosed processes can then include calculating the etch bias with the etch bias model, the etch bias representing displacements of the features from resist contour feature locations. Accordingly, the after-etch profiles described herein can be generated utilizing the etch bias.

The process flow depicted in FIG. 7 includes utilizing staircase feature mask 710 (e.g., staircase feature mask 400) with an after-development inspection (ADI) model 720 (which can also be a lithography model that includes a resist model) to generate surface features 730 (e.g., resist contours at the top level). Similarly, staircase formation mask 740 (e.g., staircase formation mask 300) can be utilized with the ADI model 720 to generate the depth map 750. One detail is that the lithography model (again that can include a resist model) can change the shape of the features (e.g., as depicted by surface feature 730 having a different shape than the feature in the staircase feature mask 710, reproduced in dashed for comparison). A similar change can occur in the staircase formation mask 740 and be carried through to the resultant depth map 750. Because the etch depths are based on the distance from the reference location 650, this change in the reference location (e.g., edge of the depth map) can affect the calculated etch depths (based on the distance between the reference location and the feature location) and hence the dimensions of the features at those etch depths.

These surface features 730 and depth map 750 can be input into the EB model 760 (Eq. 2), with the gauge data 770 utilized as described above. The output of EB model 760 (the EB) can then be utilized to predict accurate etch contours 780 of the features at all levels. As seen, the utilization of a staircase mask that captures the depth dependency based on feature position greatly reduces the computational overhead as compared to utilizing a different mask at each level. While the present disclosure describes the use of a single staircase mask, in other embodiments, the process can utilize other masks (e.g., a series of convolutions). However, the use of one (or more) masks provides computational benefits over requiring that each layer of a highly layered structure have its own mask.

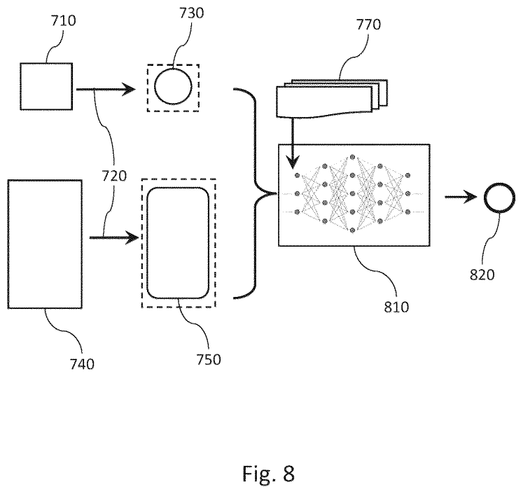

FIG. 8 illustrates an exemplary process flow for generating simulated features utilizing a machine learning model, according to an embodiment of the present disclosure. The process depicted in FIG. 8 is similar in many respects to that depicted in FIG. 7 (with corresponding elements reproduced) but instead of utilizing EB model 760 to determine the etch bias, the model can be a machine learning model 810 utilized to determine the etch bias and etch contours 820. As shown in FIG. 8, machine learning model 810 can be trained with gauge data 770, similar to that done as described for FIG. 7, but here with the gauge data being used as an input to the machine learning model 810. Here, the process can include calculating an etch bias with the machine learning model, with the etch bias again representing displacements of the features from target feature locations. Also as before, the predicted after-etch profiles can be generated utilizing the etch bias.

In another embodiment, the machine learning model itself 810 can directly predict etch contours 820 at varying depths, given a depth map 750 and resist contour (or target pattern) 730. Such an embodiment would omit the staircase formation mask 740 and machine learning model 810 would instead be provided depth map 750 directly.

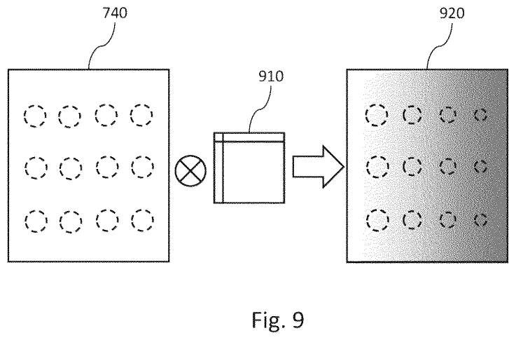

FIG. 9 illustrates an exemplary filter for use with a machine learning model, according to an embodiment of the present disclosure. In various embodiments, different machine learning models can be utilized to generate predicted after-etch profiles. Types of machine learning models can include, for example, a convolutional neural network (CNN), recurrent neural networks (RNN), artificial neural networks (ANN), etc., In the example of FIG. 9, where the machine learning model is a convolutional neural network, the filter can be a convolutional neural network filter 910. The CNN filter 910 can include weights used to represent the depths at the locations of the features. The depiction of feature size as a function of depth is also shown here, similar to that as depicted in FIG. 6. The weights can be applied to the various neurons in the layers of the CNN. The CNN can be trained according to various methods, for example trained with measurements of training features from printed wafers, trained with simulated features, etc. Similar to that shown in FIG. 6, the convolution of staircase formation mask 740 with CNN filter 910 can then generate depth map 920 that can be utilized to determine the depth dependency and thereby the etch bias values as previously described.

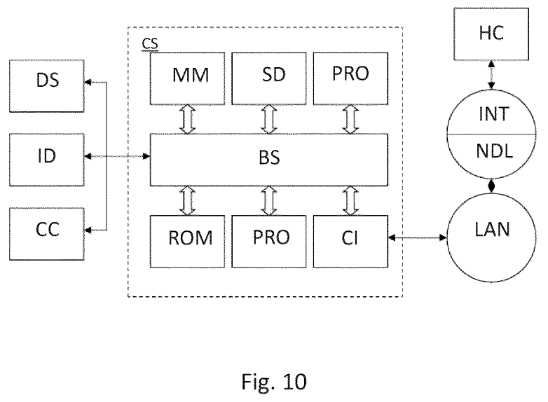

FIG. 10 is a block diagram of an example computer system CS, according to an embodiment of the present disclosure.

Computer system CS includes a bus BS or other communication mechanism for communicating information, and a processor PRO (or multiple processor) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions to be executed by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions contained in main memory MM causes processor PRO to perform the process steps described herein. One or more processors in a multi-processing arrangement may also be employed to execute the sequences of instructions contained in main memory MM. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the features described herein. Transitory computer-readable media can include a carrier wave or other propagating electromagnetic signal.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) both use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

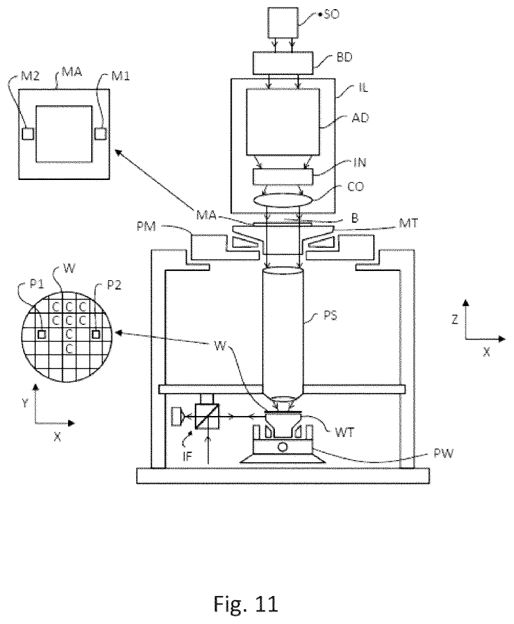

FIG. 11 is a schematic diagram of a lithographic projection apparatus, according to an embodiment of the present disclosure.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g., so as to position different target portions C in the path of beam PB. Similarly, the first positioning apparatus can be used to accurately position patterning device MA with respect to the path of beam B, e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

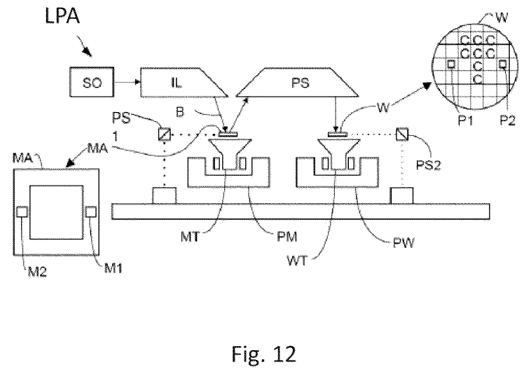

FIG. 12 is a schematic diagram of another lithographic projection apparatus (LPA), according to an embodiment of the present disclosure.

LPA can include source collector module SO, illumination system (illuminator) IL configured to condition a radiation beam B (e.g., EUV radiation), support structure MT, substrate table WT, and projection system PS.

Support structure (e.g., a patterning device table) MT can be constructed to support a patterning device (e.g., a mask or a reticle) MA and connected to a first positioner PM configured to accurately position the patterning device;

Substrate table (e.g., a wafer table) WT can be constructed to hold a substrate (e.g., a resist coated wafer) W and connected to a second positioner PW configured to accurately position the substrate.

Projection system (e.g., a reflective projection system) PS can be configured to project a pattern imparted to the radiation beam B by patterning device MA onto a target portion C (e.g., comprising one or more dies) of the substrate W.

As here depicted, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. Source collector module SO may be part of an EUV radiation system including a laser for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation.

In such cases, the laser may not be considered to form part of the lithographic apparatus and the radiation beam can be passed from the laser to the source collector module with the aid of a beam delivery system comprising, for example, suitable directing mirrors and/or a beam expander. In other cases, the source may be an integral part of the source collector module, for example when the source is a discharge produced plasma EUV generator, often termed as a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode.

In step mode, the support structure (e.g., patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

In scan mode, the support structure (e.g., patterning device table) MT and the substrate table WT are scanned synchronously while a pattern imparted to the radiation beam is projected onto target portion C (i.e. a single dynamic exposure). The velocity and direction of substrate table WT relative to the support structure (e.g., patterning device table) MT may be determined by the (de-) magnification and image reversal characteristics of the projection system PS.

In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array.

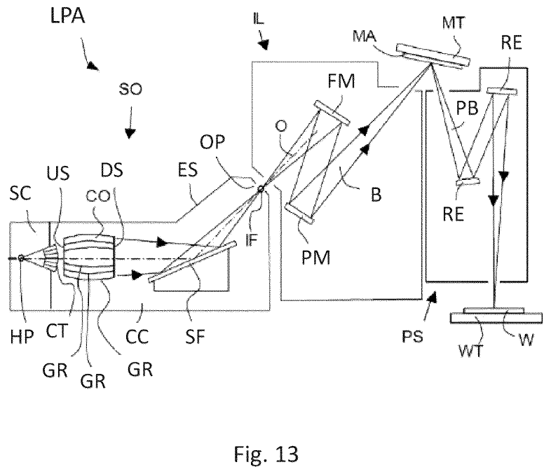

FIG. 13 is a detailed view of the lithographic projection apparatus, according to an embodiment of the present disclosure.

As shown, LPA can include the source collector module SO, the illumination system IL, and the projection system PS. The source collector module SO is constructed and arranged such that a vacuum environment can be maintained in an enclosing structure ES of the source collector module SO. An EUV radiation emitting hot plasma HP may be formed by a discharge produced plasma source. EUV radiation may be produced by a gas or vapor, for example Xe gas, Li vapor or Sn vapor in which the hot plasma HP is created to emit radiation in the EUV range of the electromagnetic spectrum. The hot plasma HP is created by, for example, an electrical discharge causing at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma HP is passed from a source chamber SC into a collector chamber CC via an optional gas barrier or contaminant trap CT (in some cases also referred to as contaminant barrier or foil trap) which is positioned in or behind an opening in source chamber SC. The contaminant trap CT may include a channel structure. Contamination trap CT may also include a gas barrier or a combination of a gas barrier and a channel structure. The contaminant trap or contaminant barrier CT further indicated herein at least includes a channel structure, as known in the art.

The collector chamber CC may include a radiation collector CO which may be a so-called grazing incidence collector. Radiation collector CO has an upstream radiation collector side US and a downstream radiation collector side DS. Radiation that traverses radiation collector CO can be reflected off a grating spectral filter SF to be focused in a virtual source point IF along the optical axis indicated by the dot-dashed line ‘O’. The virtual source point IF can be referred to as the intermediate focus, and the source collector module can be arranged such that the intermediate focus IF is located at or near an opening OP in the enclosing structure ES. The virtual source point IF is an image of the radiation emitting plasma HP.

Subsequently the radiation traverses the illumination system IL, which may include a facetted field mirror device FM and a facetted pupil mirror device PM arranged to provide a desired angular distribution of the radiation beam B, at the patterning device MA, as well as a desired uniformity of radiation amplitude at the patterning device MA. Upon reflection of the beam of radiation B at the patterning device MA, held by the support structure MT, a patterned beam PB is formed and the patterned beam PB is imaged by the projection system PS via reflective elements RE onto a substrate W held by the substrate table WT.

More elements than shown may generally be present in illumination optics unit IL and projection system PS. The grating spectral filter SF may optionally be present, depending upon the type of lithographic apparatus. Further, there may be more mirrors present than those shown in the figures, for example there may be 1-6 additional reflective elements present in the projection system PS.

Collector optic CO can be a nested collector with grazing incidence reflectors GR, just as an example of a collector (or collector mirror). The grazing incidence reflectors GR are disposed axially symmetric around the optical axis O and a collector optic CO of this type may be used in combination with a discharge produced plasma source, often called a DPP source.

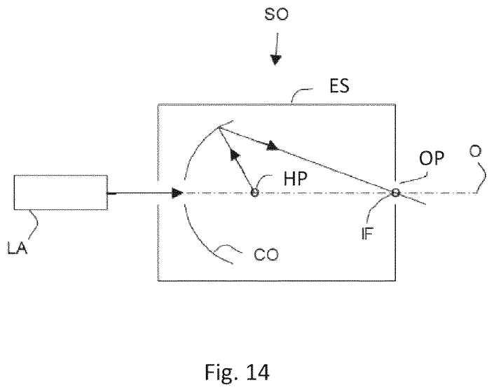

FIG. 14 is a detailed view of source collector module SO of lithographic projection apparatus LPA, according to an embodiment of the present disclosure.

Source collector module SO may be part of an LPA radiation system. A laser LA can be arranged to deposit laser energy into a fuel, such as xenon (Xe), tin (Sn) or lithium (Li), creating the highly ionized plasma HP with electron temperatures of several 10's of eV. The energetic radiation generated during de-excitation and recombination of these ions is emitted from the plasma, collected by a near normal incidence collector optic CO and focused onto the opening OP in the enclosing structure ES.

The concepts disclosed herein may simulate or mathematically model any generic imaging system for imaging sub wavelength features and may be especially useful with emerging imaging technologies capable of producing increasingly shorter wavelengths. Emerging technologies already in use include EUV (extreme ultraviolet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses.
1. A method of predicting after-etch profiles of features at varying depths, the method comprising:
   accessing after-development resist profiles of features; and
   applying an etch bias model on the after-development resist profiles to obtain the after-etch profiles, wherein the etch bias model correlates an etch bias with an etch depth.
2. The method of clause 1, wherein the etch bias is correlated with the etch depth based on a lateral location of a feature.
3. The method of clause 1, wherein the after-development resist profiles are predicted resist contours.
4. The method of clause 1, wherein the etch bias model comprises a term indicating a convolution of a mask and a filter, the convolution calculating the etch depth.
5. The method of clause 1, wherein the after-etch profiles are after-etch CDs.
6. The method of clause 1, the determining of the after-development resist profiles comprising applying a resist model to a patterning device.
7. The method of clause 1, wherein determining the etch depth is based on distances of the features from a reference location of a staircase feature mask.
8. The method of clause 7, wherein the staircase feature mask indicates locations of the features, the determining of the etch depth comprising convolving a staircase formation mask and a filter, the convolution generating a depth map representing the depths at locations of the features.
9. The method of clause 8, further comprising calibrating the etch bias model by determining a coefficient that modifies an etch bias contribution of the convolution, the coefficient calculated based on gauge data having etch bias values for the features at their respective depths.
10. The method of clause 9, wherein the gauge data is CD and/or EP gauge data for the features.
11. The method of clause 9, wherein the coefficient is calculated using a linear solver to fit measurements of printed features on printed wafers.
12. The method of clause 9, further comprising calculating the etch bias with the etch bias model, the etch bias representing displacements of the features from target feature locations, the after-etch profiles generated utilizing the etch bias.
13. The method of clause 8, wherein the filter is a square filter.
14. The method of clause 8, wherein the filter is a multi-gaussian filter.
15. The method of clause 8, wherein the etch bias model is a machine learning model trained with gauge data, the method further comprising calculating the etch bias with the machine learning model, the etch bias representing displacements of the features from target feature locations, the predicted after-etch profiles generated utilizing the etch bias.
16. The method of clause 14, wherein the machine learning model is a convolutional neural network and the filter is a convolutional neural network filter comprising weights used to represent the etch depth at the locations of the features.
17. The method of clause 14, wherein the machine learning model has been trained with measurements of training features from printed wafers.
18. A non-transitory computer readable medium having instructions recorded thereon for predicting an after-etch profile of features at varying depths, the instructions when executed by a computer having at least one programmable processor cause operations as in any of clauses 1-17.
19. A system for predicting an after-etch profile of features at varying depths, the system comprising:
   at least one programmable processor; and
   a non-transitory computer readable medium having instructions recorded thereon, the instructions when executed by a computer having the at least one programmable processor cause operations as in any of clauses 1-17.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The combinations and sub-combinations of the elements disclosed herein constitute separate embodiments and are provided as examples only. Also, the descriptions above are intended to be illustrative, not limiting. Thus, it will be apparent to one skilled in the art that modifications may be made as described without departing from the scope of the claims set out below.

1. A non-transitory computer readable medium having stored instructions, the instructions, when executed by a computer system, configured to cause the computer system to at least:
access after-development resist profiles of features at varying depths; and
apply an etch bias model on the after-development resist profiles to obtain after-etch profiles of the features, wherein the etch bias model correlates an etch bias with an etch depth.

2. The medium of claim 1, wherein the etch bias is correlated with the etch depth based on a lateral location of a feature.

3. The medium of claim 1, wherein the after-development resist profiles are predicted resist contours.

4. The medium of claim 1, wherein the etch bias model comprises a term indicating a convolution of a mask and a filter, the convolution calculating the etch depth.

5. The medium of claim 1, wherein the after-etch profiles are after-etch CDs.

6. The medium of claim 1, wherein the instructions configured to cause the computer system to determine the after-development resist profiles are further configured to cause the computer system to apply a resist model to a patterning device.

7. The medium of claim 1, wherein the instructions configured to cause the computer system to determine the etch depth are further configured to cause the computer system to determine the etch depth based on distances of the features from a reference location of a staircase feature mask.

8. The medium of claim 7, wherein the staircase feature mask indicates locations of the features, and wherein the instructions configured to cause the computer system to determine the etch depth are further configured to cause the computer system to convolve a staircase formation mask and a filter, the convolution generating a depth map representing the depths at locations of the features.

9. The medium of claim 8, wherein the instructions are further configured to cause the computer system to calibrate the etch bias model by determination of a coefficient that modifies an etch bias contribution of the convolution, the coefficient calculated based on gauge data having etch bias values for the features at their respective depths.

10. The medium of claim 9, wherein the gauge data is CD and/or EP gauge data for the features.

11. The medium of claim 9, wherein the coefficient is calculated using a linear solver to fit measurements of printed features on printed wafers.

12. The medium of claim 9, wherein the instructions are further configured to cause the computer system to calculate the etch bias with the etch bias model, the etch bias representing displacements of the features from target feature locations, the after-etch profiles generated utilizing the etch bias.

13. The medium of claim 8, wherein the filter is a square filter or a multi-Gaussian filter.

14. The medium of claim 8, wherein the etch bias model is a machine learning model trained with gauge data, and wherein the instructions are further configured to cause the computer system to calculate the etch bias with the machine learning model, the etch bias representing displacements of the features from target feature locations, the predicted after-etch profiles generated utilizing the etch bias.

15. The medium of claim 14, wherein the machine learning model is a convolutional neural network and the filter is a convolutional neural network filter comprising weights used to represent the etch depth at the locations of the features.

16. A method comprising:
accessing after-development resist profiles of features at varying depths; and
applying, by a hardware computer system, an etch bias model on the after-development resist profiles to obtain after-etch profiles of the features, wherein the etch bias model correlates an etch bias with an etch depth.

17. The method of claim 16, wherein the etch bias is correlated with the etch depth based on a lateral location of a feature.

18. The method of claim 16, wherein the after-development resist profiles are predicted resist contours.

19. The method of claim 16, wherein the etch bias model comprises a term indicating a convolution of a mask and a filter, the convolution calculating the etch depth.

20. The method of claim 16, wherein determining the etch depth is based on distances of the features from a reference location of a staircase feature mask.
